(19) United States
(12) Patent Application Publication
(10) Pub. No.: US 2018/0097274 A1
(43) Pub. Date: Apr. 5, 2018

(54) MAGNETIC RESONANCE IMAGING APPARATUS, RADIO-FREQUENCY COIL THEREFOR, AND METHOD FOR MANUFACTURING A RADIO-FREQUENCY COIL

(71) Applicant: Siemens Healthcare GmbH, Erlangen (DE)

(72) Inventor: Yan Hong Chen, Shenzhen (CN)

(73) Assignee: Siemens Healthcare GmbH, Erlangen (DE)

(21) Appl. No.: 15/720,377

(22) Filed: Sep. 29, 2017

(30) Foreign Application Priority Data
Sep. 30, 2016 (CN) 201610874085.5

(51) Int. Cl. H01Q 1/20; G01R 33/34; H01Q 1/36; B21D 11/10; B29C 31/04

(52) U.S. Cl. CPC H01Q 1/20; G01R 33/34084; G01R 33/34007; H01Q 1/00; B21D 11/10; B29C 31/04; H01Q 1/36

(57) ABSTRACT

A radio-frequency (RF) coil for magnetic resonance imaging (MRI) has a flexible antenna circuit, support that supports the flexible antenna circuit, and a one-piece flexible casing, enclosing the flexible antenna circuit and the support. A method for manufacturing such an RF coil avoids the operation of piecing-together individual components, so the RF coil has more precise dimensions, conforms better to the human body under examination, reduces signal losses, increases the SNR, reduces the number of connecting components, and lowers the material costs of the RF coil.

### BACKGROUND OF THE INVENTION

### Field of the Invention

The present invention concerns the technical field of medical equipment, in particular to a magnetic resonance imaging (MRI) apparatus, and a radio-frequency (RF) coil used for magnetic resonance imaging, and a method for manufacturing such an RF coil.

### Description of the Prior Art

In an MRI apparatus, different RF coils will be used to scan different parts of a patient. Depending on the particular part being scanned, these RF coils generally include a head/neck coil, knee coils, shoulder coils and ankle coils, etc. In general, the RF coils must satisfy the following requirements. From the patient's point of view, the RF coils must be ergonomic, and comfortably tolerable for the patient. From the operator's point of view, the RF coils should be easy to position and move. Moreover, the shape of the RF coils must match the shape of the part of the patient being imaged as closely as possible, so that there is a high fill rate, in order to increase the signal-to-noise ratio (SNR), and obtain a high-quality image. From the manufacturer's point of view, the RF coils should be easy to install, so production efficiency can be increased and costs reduced.

Chinese utility model patent CN2815275Y proposes a magnetic resonance receive coil combined structure formed by connecting at least one rigid sub-component and at least one flexible sub-component. The rigid sub-component and the flexible sub-component each comprise an internal conductor layer; the internal conductor layer of the rigid sub-component and the internal conductor layer of the flexible sub-component are connected electrically. This coil exploits the rational combination of the rigid sub-component and the flexible sub-component, such that the magnetic resonance receive coil can achieve complex shapes to meet examination requirements for different parts of the patient, while also being comfortable and tolerable.

### SUMMARY OF THE INVENTION

In view of the above, an object of the present invention is to provide an RF coil for an MRI apparatus, in order to increase the precision of dimensions, maintain the integrity of the antenna circuit to the greatest extent possible, and increase the SNR. Another object of the present invention is to provide an MRI apparatus having such an RF coil. Another object of the present invention is to provide a method for manufacturing such an RF coil.

According to one aspect of the present invention, an RF coil has a flexible antenna circuit, a support that supports the flexible antenna circuit, and a one-piece flexible casing, enclosing the flexible antenna circuit and the support.

In an embodiment, the support is made of plastic or fabric.

In another embodiment, the flexible casing is made of an elastic macromolecular material.

In another embodiment, the flexible casing is made by an injection molding method.

Optionally, the RF coil is a birdcage RF coil.

Optionally, the RF coil is a shoulder coil, a head coil, a wrist coil, a knee coil or an ankle coil.

According to another aspect of embodiments of the present invention, an MRI apparatus has an RF coil according to any of the embodiments described above.

According to another aspect of the present invention, a method for manufacturing such an RF coil has the following steps: bending a flexible antenna circuit into a desired shape and then fixing the bent flexible antenna circuit to a support, fixing the flexible antenna circuit and the support together in an elastic macromolecular material mold, and injecting an elastic macromolecular material into the elastic macromolecular material mold, such that the elastic macromolecular material encloses the flexible antenna circuit and the support, so as to form a one-piece flexible casing.

Preferably, the method further includes designing the flexible antenna circuit to have a flattenable shape, corresponding to a human body part, of the RF coil.

According to another aspect of the present invention, a method for manufacturing an RF coil has the following steps: putting an elastic macromolecular material into two molds, so as to make an outer flexible body and an inner flexible body, respectively, and bending a flexible antenna circuit into a desired shape and then fixing the bent flexible antenna circuit to a support, bonding the flexible antenna circuit and support to the outer flexible body and inner flexible body, and putting the bonded components into a third mold in order to undergo secondary shaping.

Preferably, the method further includes designing the flexible antenna circuit to have a flattenable shape, corresponding to a human body part, of the RF coil.

In the inventive solutions described above, since the flexible antenna circuit is supported on the support and enclosed by a one-piece flexible casing, such an RF coil avoids the operation of piecing-together in the prior art, therefore the RF coil has more precise dimensions, and maintains the integrity of the antenna circuit to the greatest extent possible. Since there is no piecing together, unnecessary signal losses caused by piecing together circuits are reduced, and the SNR is increased. Furthermore, since the RF coil is not pieced together but is instead formed in an integrated manner, the number of connecting components is greatly reduced, lowering the material costs effectively.

In terms of user experience, since the flexible antenna circuit and support are enclosed by the flexible casing in the RF coil provided in an embodiment of the present invention, and only flexible material comes into contact with the human body under examination during use, bodily comfort is improved in comparison with a rigid coil, and the RF coil is easier to manipulate during use.

Existing flexible coils are generally surface coils; soft sheet material is cut to the required shape, then bonded to an antenna circuit, then put into a mold to be shaped by hot pressing. The RF coil provided in an embodiment of the present invention is designed according to a part of the human body and therefore conforms to the human body better than existing flexible coils, and can also be fitted more closely to a part being scanned by applying an external force, and the SNR is steadier at different depths.

### BRIEF DESCRIPTION OF THE DRAWINGS

FIG. 1 is a schematic diagram of a flexible antenna circuit according to an embodiment of the present invention.

FIG. 2 is a schematic diagram of a flexible coil framework according to an embodiment of the present invention.

FIG. 3 is a schematic diagram of a mold according to an embodiment of the present invention.

FIG. 4 is a schematic diagram of a flexible coil component according to an embodiment of the present invention.

FIG. 5 is a schematic diagram of an RF coil according to an embodiment of the present invention.

FIG. 6 is a schematic diagram of a part of a flexible coil component according to an embodiment of the present invention.

FIGS. 7(a) and 7(b) are schematic diagrams of states of use of an RF coil according to an embodiment of the present invention.

### DESCRIPTION OF THE PREFERRED EMBODIMENTS

As used herein, “schematic” means “serving as an instance, example or illustration”. No drawing or embodiment described herein as “schematic” should be interpreted as a more preferred or more advantageous technical solution.

To make the drawings appear uncluttered, only those parts relevant to the present invention are shown schematically in the drawings; they do not represent the actual structure thereof as a product. Furthermore, to make the drawings appear uncluttered for ease of understanding, in the case of components having the same structure or function in certain drawings, only one of these is drawn schematically, or only one is marked.

At present, RF coils may be classified, according to structural form, as rigid coils, flexible coils, and combined rigid/flexible coils. Of these, flexible coils are generally used as surface coils, whereas rigid coils and combined rigid/flexible coils are generally used as birdcage coils.

A casing of a rigid coil is generally of hard plastic. Advantages of this structure are a high degree of conformity between the shape thereof and the human body, and convenient maintenance and positioning. Since the shape of a rigid coil cannot change, it has a lower degree of applicability and tolerability than a flexible coil.

In the case of a flexible coil, a casing of the coil is generally made of an elastic macromolecular material; a flexible antenna circuit is joined to the elastic macromolecular material by hot pressing or physical foaming, etc. The majority of such coils are in the form of flat boards, e.g. chest coils and abdomen coils. Advantages of flexible coils are that they are convenient to use, lightweight and adaptable, can be brought into close contact with parts being scanned of the patient, give an increased SNR, and are more comfortable and tolerable for the patient than rigid coils. However, flexible coils exhibit a lower degree of conformity to special parts such as the head, shoulders and ankles than rigid coils, and slight difficulty is encountered in positioning flexible coils due to the fact that the shape thereof can change.

In a combined rigid/flexible coil, the whole coil is divided into at least one rigid sub-component and at least one flexible sub-component; these rigid sub-components and flexible sub-components are connected together, to form the combined rigid/flexible coil by the method of piecing together. An advantage of a combined rigid/flexible coil is that it effectively combines the advantages of rigid coils and flexible coils. However, a combined rigid/flexible coil has a large number of components, production and assembly of the whole coil are more complicated, and the circuit integrity and uniformity thereof are generally inferior to those of a rigid coil or flexible coil, possibly resulting in signal losses. In the case of a small coil such as a shoulder coil, at the present time it is still not possible to use such a pieced-together combined rigid/flexible coil.

In an embodiment of the present invention, the RF coil is preferably a birdcage RF coil. The RF coil may be a shoulder coil, a head coil, a wrist coil, a knee coil, or an ankle coil, etc. The RF coil in an embodiment of the present invention is different from the pieced-together coil described above, employs a new structure, and specifically is a one-piece coil.

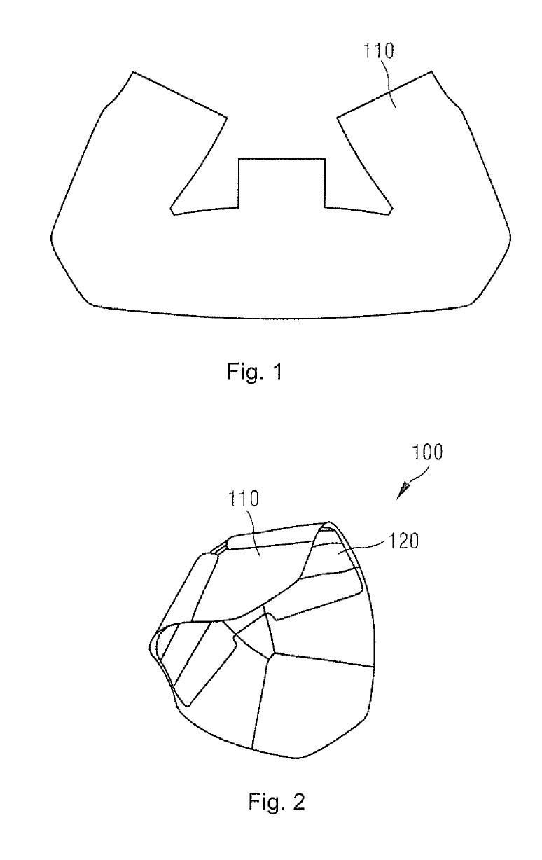

As shown in FIG. 1, an RF coil 100 according to an embodiment of the present invention has a flexible antenna circuit 110, a support 120 and a one-piece flexible casing.

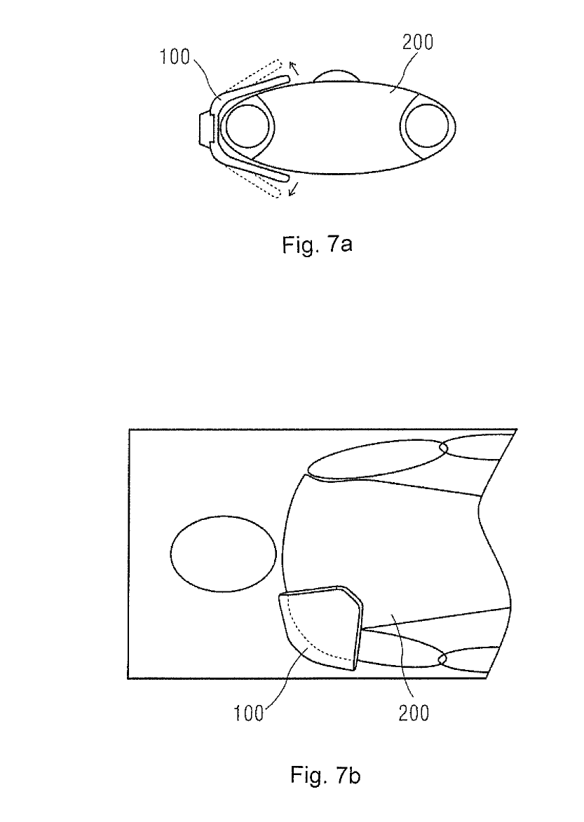

The flexible antenna circuit 110 may first be designed to have a flattenable shape, corresponding to a human body part under examination, of the RF coil 100, and then be bent into a desired shape. The flattenable shape corresponding to a human body part under examination is for example the shape shown in FIG. 1, which, after being bent, corresponds to a shoulder of the human body under examination (as shown in FIGS. 2, 7a and 7b); in other words, by opening out a shape corresponding to a shoulder of a human body under examination, a flattenable shape corresponding to the shoulder of the human body under examination can be obtained.

The support 120 is used to support the flexible antenna circuit 110. According to one embodiment of the present invention, the support 120 may be made of plastic or fabric.

The one-piece flexible casing encloses the flexible antenna circuit 110 and the support 120. In one embodiment, the flexible casing may be made of an elastic macromolecular material. Optionally, the flexible casing is made by an injection molding method.

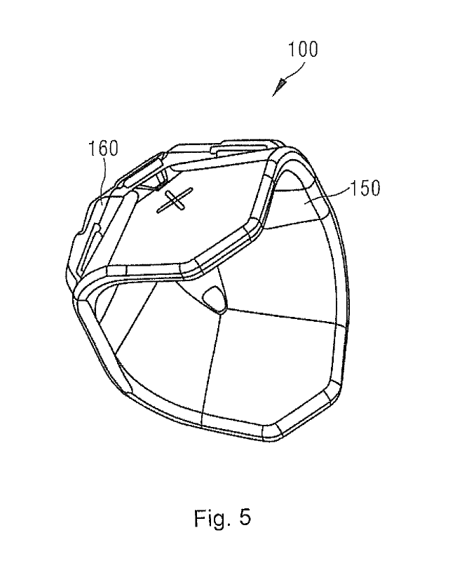

As stated above, the RF coil 100 mainly comprises a flexible coil component 150. The flexible coil component 150 includes the flexible antenna circuit 110, support 120 and one-piece flexible casing mentioned above. FIG. 5 shows a sixteen-channel shoulder coil. In FIG. 5, the RF coil 100 may also have a casing attachment 160; the casing attachment 160 is connected to the one-piece flexible casing of the flexible coil component 150. The casing attachment 160 is, for example, a handle for ease of carrying by hand.

The present invention also includes a method for manufacturing an RF coil 100 as described above. As shown in FIGS. 1 to 5, the method for manufacturing an RF coil includes Step 10, as shown in FIGS. 1 and 2, bending a flexible antenna circuit 110 into a desired shape.

Preferably, in this step, the flexible antenna circuit 110 may first be designed to have a flattenable shape, corresponding to a human body part under examination, of the RF coil, and then the flexible antenna circuit 110 may be bent into the desired shape.

Step 20, as shown in FIG. 2, fixing the flexible antenna circuit 110, which has been bent into the desired shape, to a support 120. The flexible antenna circuit 110 and support 120 form a flexible coil framework 130. The support 120 may be made of plastic or fabric.

Step 30, as shown in FIG. 3, fixing the flexible antenna circuit 110 and the support 120 together (i.e. fixing the flexible coil framework 130) in an elastic macromolecular material mold 140. As shown in FIG. 3, a demonstrative elastic macromolecular material mold 140 comprises an upper mold 141 and a lower mold 142.

An elastic macromolecular material is injected into a cavity 143 of the elastic macromolecular material mold 140, such that the elastic macromolecular material encloses the flexible antenna circuit 110 and support 120, and the elastic macromolecular material thereby forms a one-piece flexible casing.

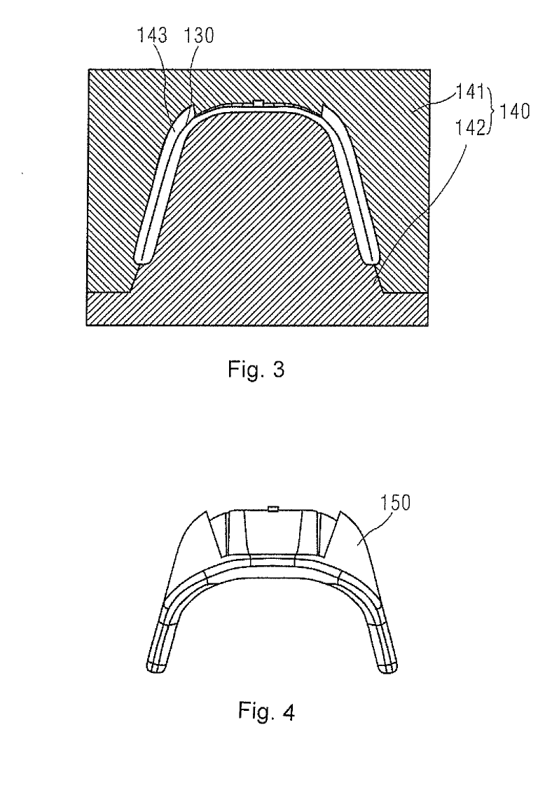

When the abovementioned steps have been performed, the flexible coil component 150 shown in FIG. 4 is obtained.

If the RF coil 100 only has the flexible coil component 150, then manufacture of the RF coil is complete. If the RF coil also has a casing attachment 160, then the manufacturing method further includes a step of connecting the casing attachment 160 to the flexible coil component 150.

The present invention also includes a method for manufacturing an RF coil as described above, and this method includes Step 50, putting an elastic macromolecular material into two molds, to make an outer flexible body 172 and an inner flexible body 173 respectively. For example, elastic macromolecular material is put into a first mold, and made into an outer flexible body 172; elastic macromolecular material is put into a second mold, and made into an inner flexible body 173.

Step 60, bending a flexible antenna circuit 110 into a desired shape and then fixing same to a support 120.

Preferably, the flexible antenna circuit 110 may first be designed to have a flattenable shape, corresponding to a human body part, of the RF coil, and then the flexible antenna circuit 110 may be bent into the desired shape.

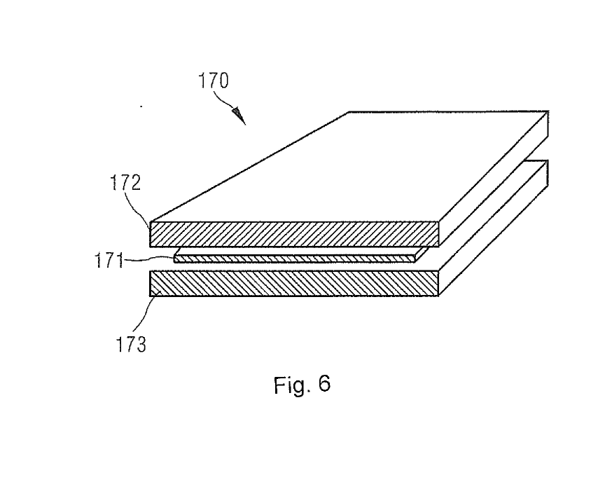

Step 70, bonding the flexible antenna circuit 110 and support 120 (which are together indicated by 171 in FIG. 6) to the outer flexible body 172 and inner flexible body 173, and putting into a third mold (not shown in the figures) to undergo secondary shaping, thereby forming a flexible coil component.

When the abovementioned steps have been performed, the flexible coil component 150 shown in FIG. 4 is obtained. If the RF coil 100 only comprises the flexible coil component 150, then manufacture of the RF coil is complete. If the RF coil also has a casing attachment 160, then the manufacturing method further includes a step of connecting the rigid coil component casing attachment 160 to the flexible coil component 150 (specifically, to a one-piece flexible casing of the flexible coil component 150).

FIG. 6 is a schematic diagram of a part 170 of a flexible coil component according to an embodiment of the present invention. As shown in FIG. 6, the outer flexible body 172 and inner flexible body 173 are made by putting an elastic macromolecular material into two molds; the flexible antenna circuit 110 is bent into a desired shape and then fixed to the support 120, the two being together indicated by the label 171; then the flexible antenna circuit 110 and support 120 (which are indicated by 171 in FIG. 6) are bonded to the outer flexible body 172 and inner flexible body 173, and put into a third mold to undergo secondary shaping. When this step has been performed, the outer flexible body 172 and inner flexible body 173 have formed a one-piece flexible casing, which encloses the flexible antenna circuit 110 and support 120.

The present invention further includes an MRI apparatus, which includes an RF coil 100 according to any of the embodiments described above.

As shown in FIGS. 7a and 7b, an RF coil 100 according to an embodiment of the present invention (specifically a shoulder coil in the figure) is arranged on a shoulder of a human body 200 under examination, thereby enabling convenient magnetic resonance imaging of the shoulder.

As stated above, embodiments of the present application concern an RF coil and a method for manufacturing such an RF coil, and an MRI apparatus that includes such an RF coil. The RF coil has a flexible antenna circuit, a support that supports the flexible antenna circuit, and a one-piece flexible casing, enclosing the flexible antenna circuit and the support. The use of the technical solution disclosed herein avoids the operation of piecing-together in the prior art, therefore the RF coil has more precise dimensions, conforms better to the human body under examination, reduces signal losses, increases the SNR, reduces the number of connecting components and lowers the material costs of the RF coil.

Although modifications and changes may be suggested by those skilled in the art, it is the intention of the Applicant to embody within the patent warranted hereon all changes and modifications as reasonably and properly come within the scope of the Applicant's contribution to the art.

1. A radio-frequency (RF) coil comprising:
a flexible antenna circuit designed to transmit or receive RF signals;
a support body that supports the flexible antenna circuit; and
a one-piece flexible casing that encloses the flexible antenna circuit and the support body.

2. An RF coil as claimed in claim 1 wherein said support body is comprised of plastic or fabric.

3. An RF coil as claimed in claim 1 wherein said flexible casing is comprised of an elastic macromolecular material.

4. An RF coil as claimed in claim 1 wherein said flexible casing is an injection-molded casing.

5. An RF coil as claimed in claim 1 wherein said flexible antenna circuit is designed as a birdcage RF coil.

6. An RF coil as claimed in claim 1 wherein said one-piece flexible casing with said flexible antenna circuit and said support enclosed therein is shaped to form a magnetic resonance coil selected from the group consisting of a shoulder coil, a head coil, a wrist coil, a knee coil, and an ankle coil.

7. A magnetic resonance apparatus comprising:
a magnetic resonance data acquisition scanner comprising a radio-frequency (RF) coil; and
said RF coil comprising a flexible antenna circuit designed to transmit or receive RF signals, a support body that supports the flexible antenna circuit, and a one-piece flexible casing that encloses the flexible antenna circuit and the support body.

8. A method for manufacturing a radio-frequency (RF) coil, comprising:
bending a flexible antenna circuit into a selected shape and then fixing the bent flexible antenna circuit with said selected shape to a support body;
fixing the bent flexible antenna circuit fixed to the support body in a mold; and
injecting an elastic macromolecular material into said mold and thereby causing said elastic macromolecular material to enclose the bent flexible antenna circuit in said selected shape fixed to the support body, forming a one-piece flexible casing.

9. A method as claimed in claim 8 comprising bending said flexible antenna circuit into a selected shape that conforms to a human body part.

10. A method for manufacturing a radio-frequency (RF) coil, comprising:
placing an elastic macromolecular material into each of two molds and, with said respective molds, molding said elastic macromolecular material into an outer flexible body and an inner flexible body;
bending a flexible antenna circuit into a selected shape and then fixing the bent flexible antenna circuit to a support body; and
bonding the bent flexible antenna circuit fixed to the support body to the outer flexible body and to the inner flexible body, thereby forming a bonded assembly, and placing the bonded assembly into a further mold and implementing secondary shaping of said bonded assembly in said further mold.

11. A method as claimed in claim 10 comprising bending said flexible antenna circuit into a selected shape that conforms to a human body part.
